(19) United States
(12) Patent Application Publication
(10) Pub. No.: US 2014/0036431 A1
(43) Pub. Date: Feb. 6, 2014

(54) PIEZOELECTRIC ACTUATOR AND ELECTRONIC DEVICE HAVING PIEZOELECTRIC ACTUATOR MOUNTED THEREON

(71) Applicants: Yasuhiro Sasaki, Tokyo (JP); Masatake Takahashi, Tokyo (JP); Hiroshi Sakai, Tokyo (JP); Tatsuya Uchikawa, Tokyo (JP); Yoshiyuki Yamaguchi, Tokyo (JP); Nobuhiro Kawashima, Tokyo (JP)

(72) Inventors: Yasuhiro Sasaki, Tokyo (JP); Masatake Takahashi, Tokyo (JP); Hiroshi Sakai, Tokyo (JP); Tatsuya Uchikawa, Tokyo (JP); Yoshiyuki Yamaguchi, Tokyo (JP); Nobuhiro Kawashima, Tokyo (JP)

(73) Assignee: NEC CORPORATION, Tokyo (JP)

(21) Appl. No.: 14/112,513

(22) PCT Filed: Apr. 19, 2012
(86) PCT No.: PCT/JP2012/060638

§ 371 Date: Oct. 17, 2013

(30) Foreign Application Priority Data
Apr. 19, 2011 (JP) 2011-093276

(51) Int. Cl. H01L 41/053; G06F 1/16

(52) U.S. Cl. CPC H01L 41/053; G06F 1/1601
USPC 361/679.21; 310/348; 310/323.01

(57) ABSTRACT

A piezoelectric actuator comprises: a piezoelectric ceramic vibrator (2) which vibrates when a voltage is applied to electrodes; a first holder (3) which is joined to a panel (502) and supports one end portion of the piezoelectric ceramic vibrator (2); and a second holder (4) which is joined to the panel (502) and supports the other end portion of the piezoelectric ceramic vibrator (2). The vibrations generated in the piezoelectric ceramic vibrator (2) are transmitted to the panel (502) via the one end portion of the piezoelectric ceramic vibrator (2) and the first holder (3), and the relative movements of the other end portion of the piezoelectric ceramic vibrator (2) in the lengthwise and crosswise directions with respect to the panel (502) are constrained by the second holder (4).

### TECHNICAL FIELD

The present invention relates to a piezoelectric actuator used as a vibrator for vibrating an electronic device and an electronic device having the piezoelectric actuator thereon.

### BACKGROUND ART

Recently, a compact electronic device having portability such as a mobile phone apparatus, a notebook-sized personal computer, a PDA, or the like, is being actively used. The convenience of the devices is being increased with the development of network system and software. Each of the devices is provided with vibration component for applying vibration to the device by vibration, and improvement in quality and miniaturization of internal components including the vibration component is in strong demand. As such a vibration component, for instance, a piezoelectric actuator using a piezoelectric ceramic vibrator disclosed in Non Patent Literature 1 is known.

### CITATION LIST

### Non Patent Literature

Non Patent Literature 1: “Applications of piezoelectric ceramics”, Gakken-sha, 1989, p. 71.

### SUMMARY OF INVENTION

### Technical Problem

In a piezoelectric actuator disclosed in Non Patent Literature 1, a piezoelectric ceramic vibrator is supported at one end of the piezoelectric ceramic vibrator by a holder joined to a case. Vibration generated by bending vibration or the like of a piezoelectric ceramic vibrator is transmitted to a case via a holder.

When a piezoelectric ceramic vibrator vibrates, inertia force is generated in piezoelectric ceramic vibrator in accordance with the vibration. The inertia force is transmitted as vibration to the holder to which the piezoelectric ceramic vibrator is fixed. A component of inertia force in a direction parallel to the main surface of the case does not contribute to vibration transmission from the holder to the case. When the vibration energy of the piezoelectric ceramic vibrator is consumed by the vibration in the parallel direction, the amount of vibration propagated from the piezoelectric ceramic vibrator to the case decreases, leading to energy loss.

The present invention has been achieved in consideration of the above-described actual conditions, and an object of the invention is to provide a piezoelectric actuator capable of efficiently transmitting vibration and an electronic device having the piezoelectric actuator mounted thereon.

### Solution to Problem

To achieve the object, a piezoelectric actuator according to a first aspect of the present invention comprises:

a piezoelectric ceramic vibrator that vibrates in a predetermined direction when electronic power is supplied;

a first holder connected to a plate-shaped member and supporting a first portion in the piezoelectric ceramic vibrator; and

a second holder connected to the plate-shaped member and supporting a second portion in the piezoelectric ceramic vibrator,

wherein the first holder is made of a material with rigidity to such a degree that it is deformed by vibration from the piezoelectric ceramic vibrator, the second holder is made of a material with rigidity to such a degree that it is not deformed by vibration from the piezoelectric ceramic vibrator,

the piezoelectric ceramic vibrator transmits vibration to the plate-shaped member via the piezoelectric ceramic vibrator and the first holder, and relative movement in the second portion of the piezoelectric ceramic vibrator with respect to the plate-shaped member is constrained by the second holder.

An electronic device according to a second aspect of the present invention comprises a case provided with a display, wherein

the plate-shaped member is a panel protecting the display, and

the piezoelectric actuator according to the first aspect is disposed in the panel.

According to the present invention, it is possible to provide a piezoelectric actuator efficiently transmitting vibration and an electronic device having the piezoelectric actuator mounted thereon.

### BRIEF DESCRIPTION OF DRAWINGS

FIG. 1 is a perspective view illustrating a piezoelectric actuator according to a first embodiment of the invention;

FIG. 2 is a schematic configuration diagram illustrating a piezoelectric ceramic according to the embodiments of the invention;

FIG. 3 is an exploded perspective view illustrating an electronic device on which the piezoelectric actuator according to the first embodiment is mounted;

FIG. 4 is a perspective view illustrating a piezoelectric actuator according to a second embodiment of the invention;

FIG. 5 is an exploded perspective view illustrating a mobile phone apparatus on which the piezoelectric actuator according to the second embodiment is mounted;

FIG. 6A is a perspective view illustrating a piezoelectric actuator according to a third embodiment of the invention;

FIG. 6B is a perspective view illustrating a modification of the piezoelectric actuator according to the third embodiment;

FIG. 7 is an exploded perspective view illustrating a mobile phone apparatus on which the piezoelectric actuator according to the third embodiment is mounted;

FIG. 8 is a perspective view illustrating a modification of the piezoelectric actuator according to the third embodiment;

FIG. 9 is a perspective view illustrating a mobile phone apparatus on which a piezoelectric actuator according to a fourth embodiment of the invention is mounted;

FIG. 10A is a schematic view illustrating a piezoelectric ceramic according to a modification of the invention;

FIG. 10B is a schematic view illustrating a piezoelectric ceramic according to a modification of the invention;

FIG. 11A is a cross-sectional view illustrating a method of joining the piezoelectric actuator to a case according to a modification of the invention;

FIG. 11B is a cross-sectional view illustrating a method of joining the piezoelectric actuator to a case according to a modification of the invention; and

FIG. 12 is a perspective view illustrating a mobile phone apparatus on which the piezoelectric actuator according to the embodiments of the invention is mounted.

### DESCRIPTION OF EMBODIMENTS

Hereinafter, a piezoelectric actuator according to the embodiments of the present invention and an electronic device having the piezoelectric actuator mounted thereon will be described with reference to the drawings.

### First Embodiment

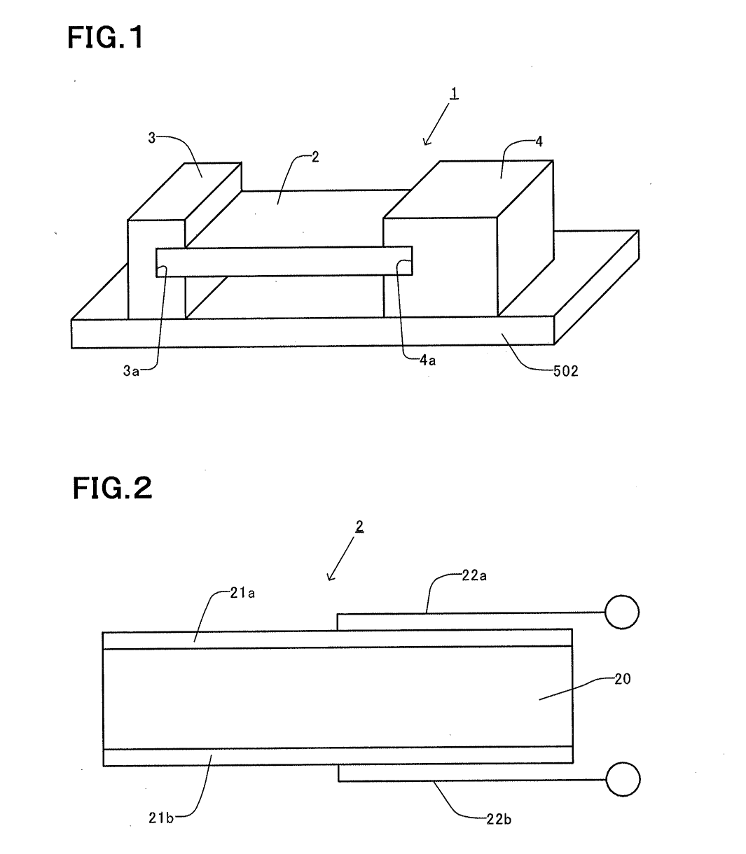

A piezoelectric actuator 1 of a first embodiment includes, as illustrated in FIG. 1, a piezoelectric ceramic vibrator 2 having a rectangular plate shape and a first holder 3 and a second holder 4 supporting both ends of the piezoelectric ceramic vibrator 2, respectively. The piezoelectric actuator 1 is joined to a panel (plate-shaped member) 502 having a rectangular plate shape via the first holder 3 and second holder 4.

As illustrated in FIG. 2, the piezoelectric ceramic vibrator 2 includes a single piezoelectric ceramic plate 20 having a rectangular plate shape and two electrodes 21a and 21b each having a rectangular plate shape and sandwiching the piezoelectric ceramic plate 20. The piezoelectric ceramic plate 20 is made of zirconate titanate and is subjected to polarization treatment in the thickness direction. The electrodes 21a and 21b are made of silver and formed on both main surfaces in the thickness direction of the piezoelectric ceramic plate 20, respectively (the front surface and the back surface of the piezoelectric ceramic plate 20 illustrated in FIG. 2). Terminals 22a and 22b are connected to the electrodes 21a and 21b, respectively. When voltage is applied to the terminals 22a and 22b, the piezoelectric ceramic plate 20 constructed as described above vibrates in the longitudinal direction (the direction of the long sides of the rectangular shape).

The first holder 3 is formed of an elastic material such as silicon rubber in an almost rectangular parallelepiped shape. The first holder 3 has rigidity to a degree that it enables the first holder 3 to be flexibly deformed by vibration of the piezoelectric ceramic vibrator 2. In one of side faces of the first holder 3 (the face facing the piezoelectric ceramic plate 20), a notch 3a whose width in the vertical direction in FIG. 1 (which will be similarly described in the following description) is almost equal to the thickness of the piezoelectric ceramic vibrator 2 is formed. One end of the piezoelectric ceramic vibrator 2 is fit in the notch 3a in the first holder 3 and fixed in the fitting portion by, for instance, an epoxy resin adhesive. The bottom surface of the first holder 3 is flat and joined to the main surface of the panel 502 by, for instance, an epoxy resin adhesive.

The second holder 4 is formed of the same material as that of the first holder 3 (here, it is silicon rubber or the like) in an almost rectangular parallelepiped shape. Like the first holder 3, in one of side surfaces of the second holder 4 (the face facing the piezoelectric ceramic plate 20), a notch 4a whose width in the vertical direction is almost equal to the thickness of the piezoelectric ceramic vibrator 2 is formed. The other end of the piezoelectric ceramic vibrator 2 is fit in the notch 4a in the second holder 4 and fixed in the fitting portion by, for instance, an epoxy resin adhesive. The bottom surface of the second holder 4 is flat and joined to the panel 502 via, for instance, an epoxy resin adhesive. The second holder 4 is formed so that the area of the bottom surface is larger than that of the first holder 3 and the height is almost equal to that of the first holder 3. Therefore, the second holder 4 has volume larger than that of the first holder 3 and has mechanical rigidity higher than that of the first holder 3. Specifically, the second holder 4 is hardly deformed in the front and rear directions and in the right and left directions in FIG. 1 (which will be similarly described in the following description) by the vibration of the piezoelectric ceramic vibrator 2. Consequently, the second holder 4 has rigidity to a degree that relative movement in the front and rear directions and in the right and left directions for the panel 502, of the other end of the piezoelectric ceramic vibrator 2 is possible to be constrained.

Next, the operation of the piezoelectric actuator 1 of the first embodiment constructed as described above will be described.

In the first embodiment, the piezoelectric ceramic plate 20 is polarized in the thickness direction. When AC voltage is applied from the electric terminals 22a and 22b to the piezoelectric ceramic plate 20 via the electrodes 21a and 21b, respectively, the piezoelectric ceramic plate 20 expands/contracts in the longitudinal direction. By the expansion/contraction in the longitudinal direction of the piezoelectric ceramic plate 20, a longitudinal vibration occurs in the piezoelectric ceramic vibrator 2. As a result, the vibration of the piezoelectric ceramic vibrator 2 is transmitted to the first and second holders 3 and 4 fixed at both ends.

The first holder 3 is made of a resin material, rubber, or elastomer material whose rigidity is low to such a degree that it is deformed by the vibration from the piezoelectric ceramic vibrator 2. Consequently, when the vibration is transmitted from the piezoelectric ceramic vibrator 2, the first holder 3 is deformed by the vibration. The vibration by the deformation is transmitted to the panel 502. Since one end of the piezoelectric ceramic vibrator 2 is fit in the notch 3a in the first holder 3, the side face of the one end and a portion of both of the main surfaces of the piezoelectric ceramic vibrator 2 are in contact with the first holder 3. Therefore, the vibration of the piezoelectric ceramic vibrator 2 is efficiently transmitted to the first holder 3 from the side faces of the piezoelectric ceramic vibrator 2 and both of the main surfaces.

On the other hand, the second holder 4 is made of a resin material whose rigidity is high to a degree that it is hardly deformed by the vibration from the piezoelectric ceramic vibrator 2. Consequently, even when the vibration is transmitted from the piezoelectric ceramic vibrator 2, the second holder 4 is hardly deformed by the vibration in the front and rear directions and the right and left directions. Since the other end of the piezoelectric ceramic vibrator 2 is supported by the second holder 4 having high rigidity, relative movement in the front and rear directions and the right and left directions of the other end of the piezoelectric ceramic vibrator 2 with respect to the panel 502 is constrained. As a result, vibration components in the front and rear directions and the right and left directions by the inertia force are suppressed. When generation of the vibration components in the front and rear directions and the right and left directions is suppressed as described above, vibration from the piezoelectric ceramic vibrator 2 is efficiently transmitted to the first holder 3. As a result, the vibration from the piezoelectric ceramic vibrator 2 is efficiently transmitted to the panel 502 via the first holder 3. Since the vibration from the piezoelectric ceramic vibrator 2 is efficiently transmitted to the panel 502, the piezoelectric ceramic vibrator 2 is vibrated in a wide frequency domain. Moreover, since the other end of the piezoelectric ceramic vibrator 2 is fit in the notch 4a in the second holder 4, the side face and a portion of both of the main surfaces of the other end of the piezoelectric ceramic vibrator 2 are in contact with the second holder 4. The side face and both of the main surfaces of the piezoelectric ceramic vibrator 2 are supported by the second holder 4 having high rigidity, so that the other end of the piezoelectric ceramic vibrator 2 is firmly fixed, and relative movement in the front and rear directions and the right and left directions with respect to the panel 502, of the other end is efficiently suppressed.

Next, an electronic device on which the piezoelectric actuator 1 of the first embodiment constructed as described above is mounted will be described using a mobile phone apparatus 500 as an example.

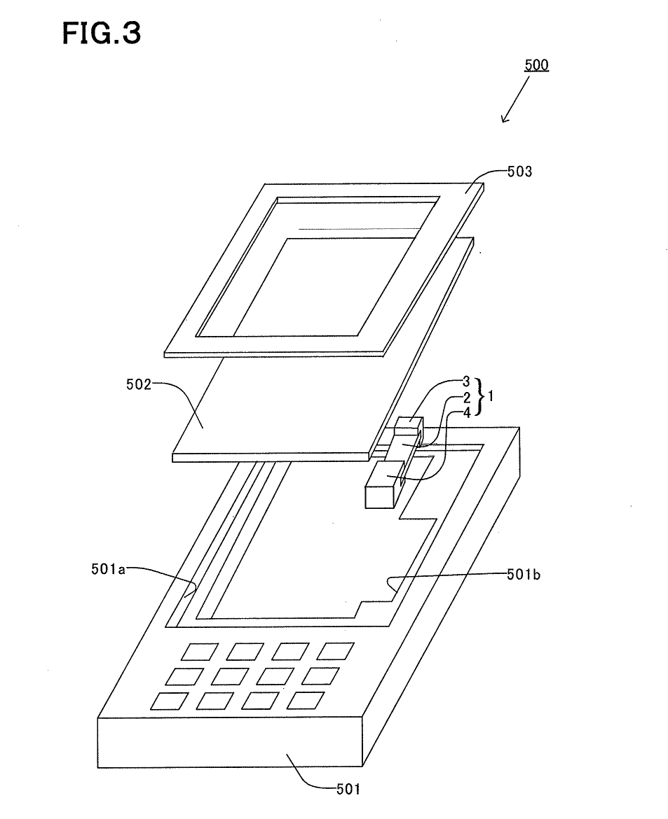

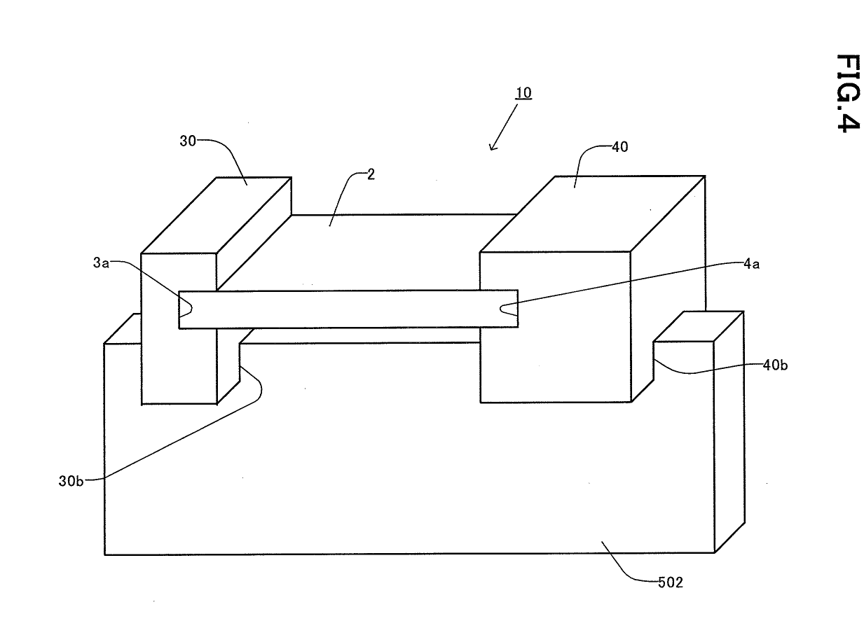

As illustrated in FIG. 3, the mobile phone apparatus 500 has a case body (case) 501 provided with input keys, a screen display, and the like, a panel 502 disposed so as to be overlapped on the case body 501, and a case cover 503. The case body 501 is formed of a resin material in a rectangular plate shape. In the main surface of the case body 501, a bottomed recess 501a having a rectangular outer shape and having a rectangular opening in its center portion is formed. In the bottomed recess 501a, the panel 502 and the case cover 503 are fit. In the bottomed recess 501a, a slit 501b in which the piezoelectric actuator 1 is further engaged and fixed, is formed.

The panel 502 is made of a transparent material such as acrylic resin, polycarbonate, polyethylene terephthalate, silica glass, or the like and protects the screen display and the like of the case body 501 from an external contact. The panel 502 is fit in the bottomed recess 501a in the case body 501, and the peripheral portion of the panel 502 is joined to the case body 501 via, for instance, an epoxy resin adhesive. To the face opposed to the case body 501 of the panel 502, the bottom surfaces of the first and second holders 3 and 4 of the piezoelectric actuator 1 are joined via, for instance, an epoxy resin adhesive: The piezoelectric actuator I is engaged and fixed in the slit 501b in the case body 501.

The case cover 503 is formed of a resin material in a manner similar to the case body 501 and is formed in a rectangular plate shape having a rectangular opening in its center portion. The case cover 503 is joined to the peripheral portion of the panel 502 via, for instance, an epoxy resin adhesive and is fit in the bottomed recess 501a in the case body 501.

When the piezoelectric ceramic vibrator 2 of the piezoelectric actuator 1 is made to vibrate, the vibration of the piezoelectric ceramic vibrator 2 is transmitted to each of the first and second holders 3 and 4 fixed at both ends. Since the first holder 3 has the rigidity lower than that of the second holder 4, when the vibration of the piezoelectric ceramic vibrator 2 is transmitted, the first holder 3 is deformed by the vibration. As a result, the vibration due to the deformation is transmitted to the panel 502 via the first holder 3. On the other hand, the second holder 4 has rigidity higher than that of the first holder 3. Consequently, even when vibration is transmitted from the piezoelectric ceramic vibrator 2, deformation in the front and rear directions and the right and left directions hardly occurs. In the piezoelectric ceramic vibrator 2, relative movement in the front and rear directions and the right and left directions with respect to the panel 502 of the other end supported by the second holder 4 having high rigidity is constrained by the second holder 4.

Since the relative movement in the direction parallel to the panel 502 of the other end of the piezoelectric ceramic vibrator 2 is constrained as described above, generation of a vibration component in the parallel direction by the inertia force in the piezoelectric ceramic vibrator 2 is suppressed. As a result, the vibration from the piezoelectric ceramic vibrator 2 is efficiently transmitted to the first holder 3, and is transmitted to the panel 502 via the first holder 3. Since the vibration from the piezoelectric ceramic vibrator 2 is efficiently transmitted to the panel 502, it is possible for the piezoelectric ceramic vibrator 2 to vibrate in a wide frequency domain. Consequently, in the case of using the piezoelectric actuator 1 as a vibrating member in the mobile phone apparatus 500, it is also possible to cause the piezoelectric actuator 1 to function as a vibrator notifying the user of reception of a call.

### Second Embodiment

In the first embodiment, the piezoelectric actuator 1 is fixed to the panel 502 by joining the bottom surfaces of the first and second holders 3 and 4 which are made flat to the panel 502. However, the invention is not limited to the method of joining the first and second holders 3 and 4 and the panel 502. Hereinafter, another joining method will be described. In the drawings to be referred to later, the same reference numerals are designated to components having the same structure and the same function, and repetitive description will not be given.

In a second embodiment, as illustrated in FIG. 4, notches 30b and 40b are formed in the bottom surfaces of a first holder 30 and a second holder 40, respectively, of a piezoelectric actuator 10. Each of the notches 30b and 40b is formed having thickness which is almost the same as that of the panel 502. By fitting one of ends of the panel 502 to the notches 30b and 40b in the first and second holders 30 and 40, the first and second holders 30 and 40 and the panel 502 are fixed.

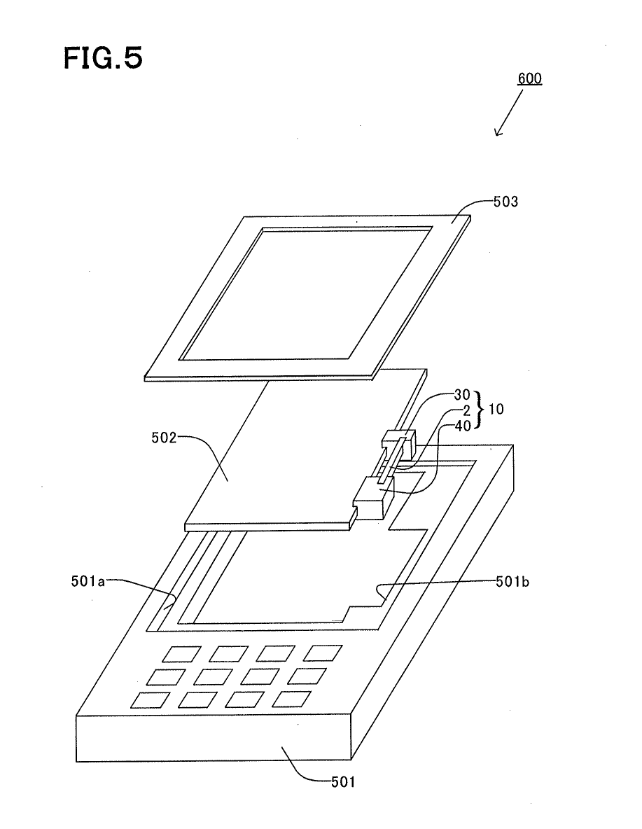

In the case of mounting the piezoelectric actuator 10 of the second embodiment on a mobile phone apparatus 600, as illustrated in FIG. 5, the notches 30b and 40b in the first and second holders 30 and 40 are fit on both side faces of the panel 502 and joined via, for instance, an epoxy resin adhesive. By the fitting of the first and second holders 30 and 40 and the panel 502, as compared with the first embodiment, the strength of the joining between the first and second holders 30 and 40 and the panel 502 is further increased, and it is possible for the vibration of the piezoelectric actuator 10 to be transmitted to the panel 502 more efficiently.

### Third Embodiment

In each of the first and second embodiments, one piezoelectric actuator 1 or 10 is joined to the panel 502 In contrast, in a third embodiment, a mode of providing a plurality of piezoelectric actuators will be described. Hereinafter, an embodiment of providing two piezoelectric actuators 100a and 100b will be described. In the drawings to be referred to later, the same reference numerals are designated to components having the same structure and the same function, and repetitive description will not be given.

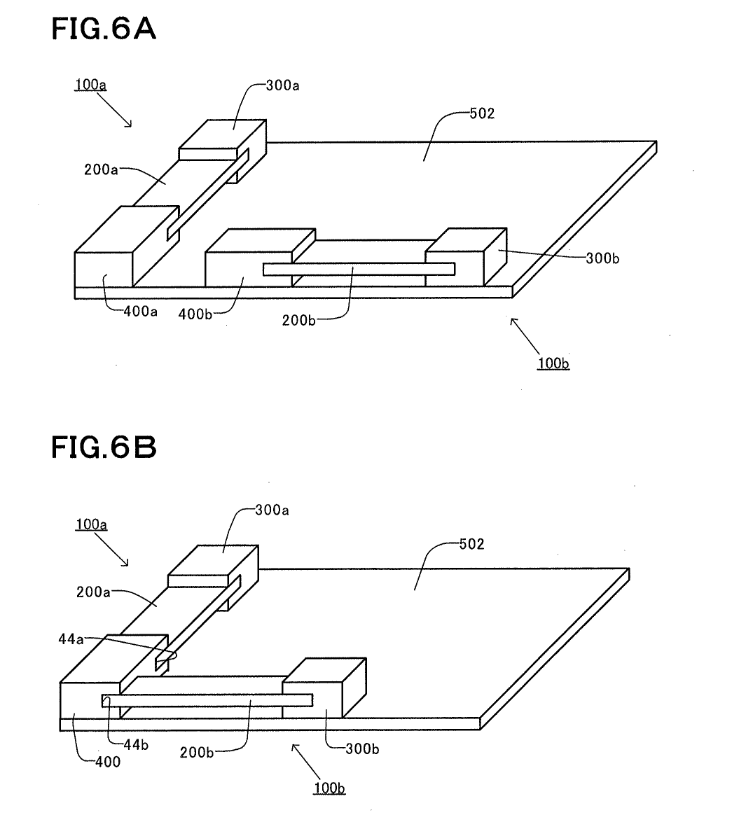

In the third embodiment, as illustrated in FIG. 6A, the two first and second actuators 100a and 100b are joined to the panel 502. In a manner similar to the piezoelectric actuator 1 of the first embodiment, the first and second piezoelectric actuators 100a and 100b include piezoelectric ceramic vibrators 200a and 200b, first holders 300a and 300b fixed to one end of the piezoelectric ceramic vibrators 200a and 200b, and second holders 400a and 400b fixed to the other end of the piezoelectric ceramic vibrators 200a and 200b, respectively. The sizes of the piezoelectric ceramic vibrators 200a and 200b, the first holders 300a and 300b, and the second holders 400a and 400b of the first and second piezoelectric actuators 100a and 100b may be different from each other.

The first piezoelectric actuator 100a is disposed in the short-side direction of the panel 502, and the second piezoelectric actuator 100b is disposed in the long-side direction of the panel 502 as a direction perpendicular to the longitudinal direction of the first piezoelectric actuator 100a. Joining the two first and second piezoelectric actuators 100a and 100b to the panel 502 as described above makes it possible for the vibration amount of the panel 502 to be further increased. By such increase in the vibration amount, it is possible for the first and second piezoelectric actuators 100a and 100b to vibrate in a wider frequency domain.

As illustrated in FIG. 6B, it is also possible to commonly use a second holder 400 of the first and second piezoelectric actuators 100a and 100b and fix one end of each of the first and second piezoelectric ceramic vibrators 200a and 200b in the first and second piezoelectric actuators 100a and 100b by the single second holder 400. In this case, a notch 44a is formed in one of the side faces of the second holder 400, and a notch 44b is formed in the other of the side faces. The first and second piezoelectric ceramic vibrators 200a and 200b are fit in the notches 44a and 44b, respectively and joined to the second holder 400 by an adhesive or the like.

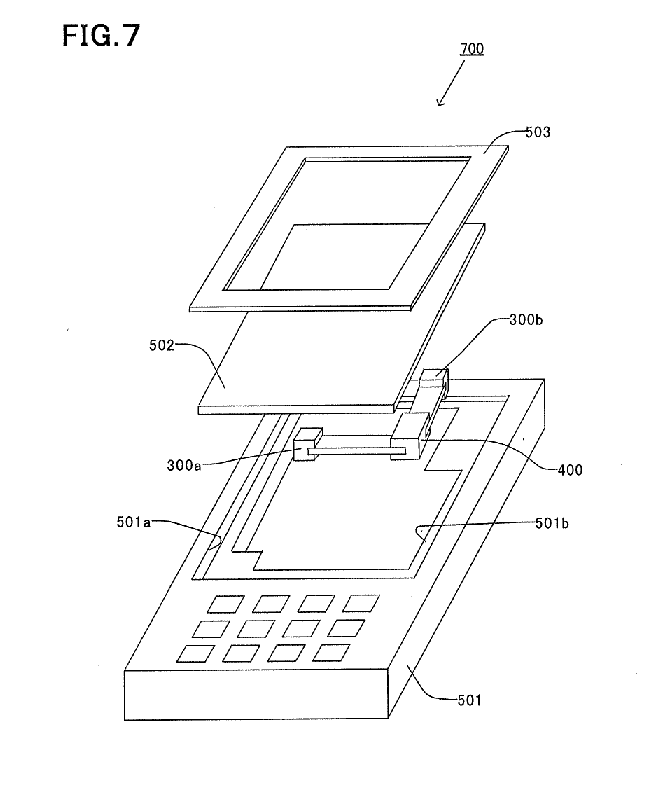

In the case of mounting the first and second piezoelectric actuators 100a and 100b on a mobile phone apparatus 700, as illustrated in FIG. 7, the bottom surface of each of the two first holders 300a and 300b and the shared second holder 400 is joined to the face opposed to the case body 501 of the panel 502 via, for instance, an epoxy resin adhesive. In the bottomed recess 501a in the case body 501, the slit 501b matching the shape of the first and second piezoelectric actuators 100a and 100b is formed, and the first and second piezoelectric actuators 100a and 100b are fit in the slit 501b.

As illustrated in FIG. 6B, in the case of sharing the second holder 400 by the first and second piezoelectric actuators 100a and 100b, three holders, the first holders 300a and 300b and the second holder 400, are sufficient. Since the first and second piezoelectric actuators 100a and 100b are integrated, as compared with the case of joining the first and second piezoelectric actuators 100a and 100b individually to the panel 502, it is possible to shorten the joining time and to reduce the manufacture cost.

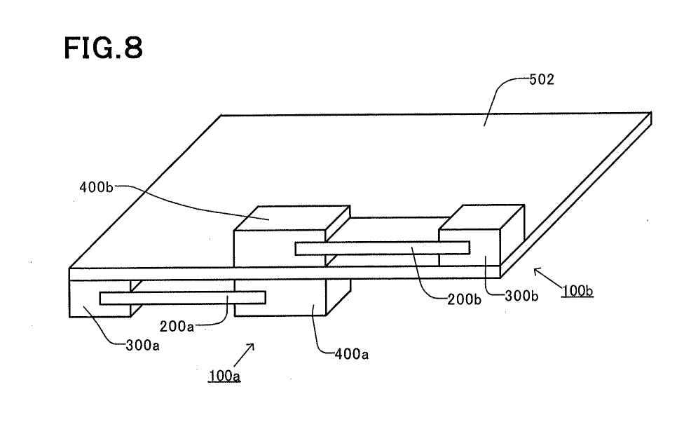

In the third embodiment, both the first and second piezoelectric actuators 100a and 100b are joined to one of the faces of the panel 502. However, as illustrated in FIG. 8, it is possible for the first and second piezoelectric actuators 100a and 100b to be disposed parallel to each other. As illustrated in FIG. 8, the first and second piezoelectric actuators 100a and 100b may be joined to different faces of the panel 502. The number of the piezoelectric actuators is not limited to two. Three or more piezoelectric actuators may be joined to the panel 502. Three or more piezoelectric actuators may share one second holder 400.

### Fourth Embodiment

In the first to third embodiments, each of the mobile phone apparatuses 500, 600, and 700 has the case body 501, the panel 502 disposed so as to overlap the case body 501, and the case cover 503. However, the configuration of the mobile phone apparatus is not limited to the above. Hereinafter, a mobile phone apparatus 800 having first and second elastic members 504a and 504b will be described. In the diagrams to be referred to later, the same reference numerals are designated to components having the same structure and the same function, and repetitive description will not be given.

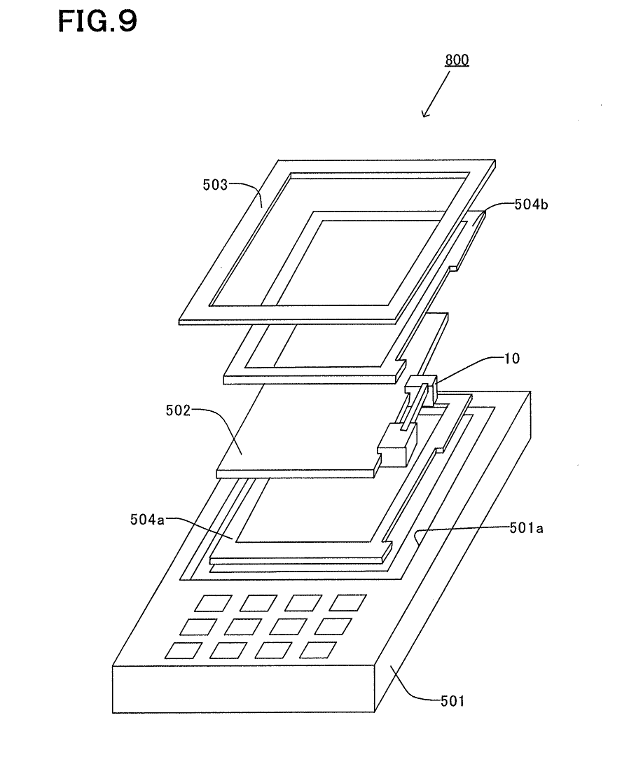

As illustrated in FIG. 9, the mobile phone apparatus 800 has the case body 501, the panel 502, the case cover 503, a first elastic member 504a and a second elastic member 504b. The first elastic member 504a is disposed between the case body 501 and the panel 502. The second elastic member 504b is disposed between the panel 502 and the case cover 503.

Each of the first and second elastic members 504a and 504b is made of an elastic material such as silicon rubber and formed in an annular rectangular plate shape. The outer periphery of the first and second elastic members 504a and 504b is larger than that of the panel 502, and the inner periphery of the first and second elastic members 504a and 504 is smaller than the outer periphery of the panel 502. The first and second elastic members 504a and 504b are disposed on both sides in the vertical direction of the peripheral portion of both of the main surfaces of the panel 502. Since the first elastic member 504a is joined to the case cover 503 and the second elastic member 504b is joined to the case body 501, the panel 502 is joined to the case body 501 and the case cover 503 via the first and second elastic members 504a and 504b.

In the mobile phone apparatus 800 of a fourth embodiment, the case body 501, the panel 502, and the case cover 503 are joined via the first and second elastic members 504a and 504b. Consequently, the peripheral portion of the panel 502 is disposed between the case body 501 and the case cover 503 so as to amplify the vibration by the first and second elastic members 504a and 504b. Therefore, as compared with the case of joining the panel 502 without the first and second elastic members 504a and 504b, it is possible for the vibration of the panel 502 by the vibration from the piezoelectric actuator 10 to be further amplified.

As above, the embodiments of the present invention have been variously described, without departing from the spirit and scope in a broad sense of the invention, other various embodiments and modifications are possible. The foregoing embodiments are provided to explain the present invention, not to limit the scope of the present invention.

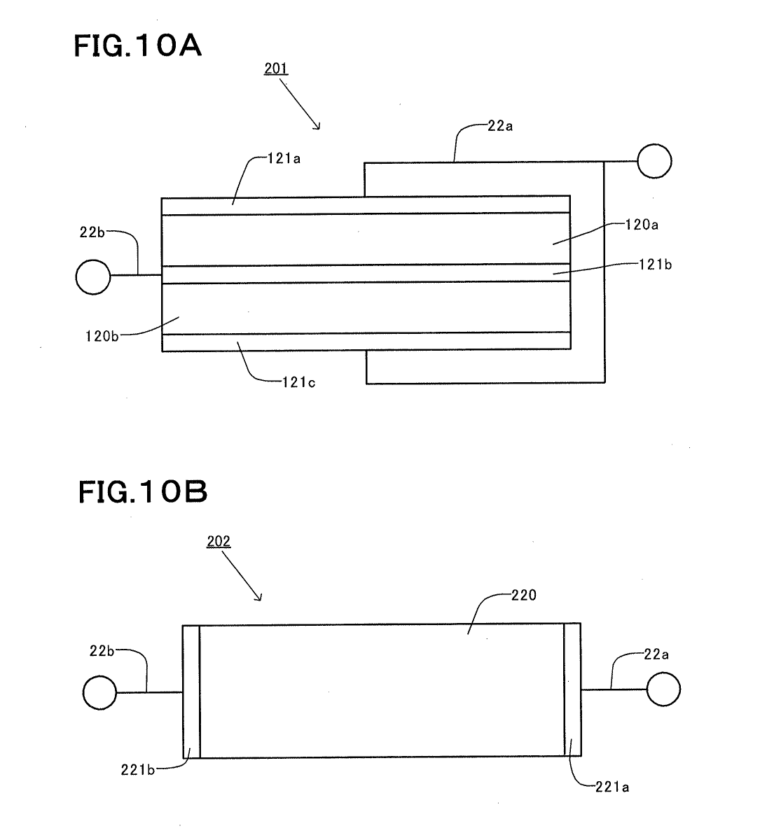

For instance, in the first to fourth embodiments, each of the piezoelectric ceramic vibrators 2, 200a, and 200b includes one piezoelectric ceramic plate 20 and the two electrodes 21a and 21b formed on both main surfaces in the thickness direction of the piezoelectric ceramic plate 20. However, as illustrated in FIG. 10A, the piezoelectric ceramic vibrator 201 may be constructed by alternately stacking two piezoelectric ceramic plates 120a and 120b and three electrodes 121a, 121b, and 121c. As illustrated in FIG. 10B, the piezoelectric ceramic vibrator 202 may be constructed by one piezoelectric ceramic plate 220 and two electrodes 221a and 221b formed on both side faces in the long-side direction (longitudinal direction) of the piezoelectric ceramic plate 220. Further, by sandwiching a reinforcing member between a plurality of piezoelectric ceramic vibrators and integrally joining them, a set of piezoelectric ceramic vibrators may be constructed. Modifying the configuration of the piezoelectric ceramic vibrator as described above, enables the vibration pattern of the piezoelectric actuator to be changed.

In the first to fourth embodiments, by setting the shape of the second holders 4, 40, 400, 400a, and 400b to be larger than that of the first holders 3, 30, 300a, and 300b, the rigidity of the second holders 4, 40, 400, 400a, and 400b is made higher than that of the first holders 3, 30, 300a, and 300b. Alternately, by changing the method of joining to the plate-shaped member, the rigidity may be changed.

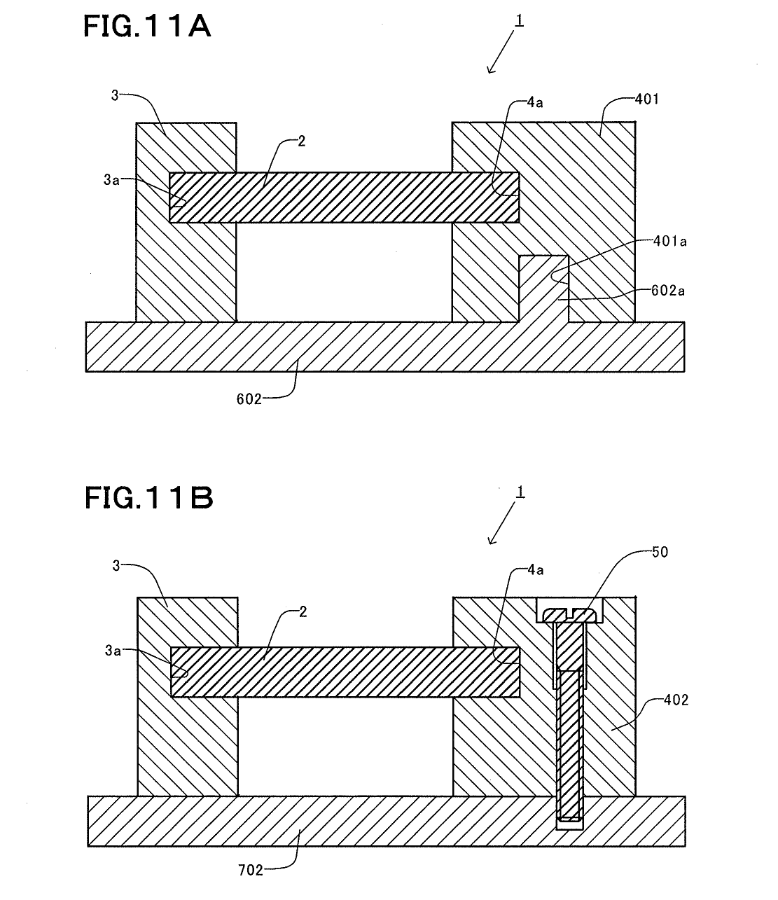

For instance, as illustrated in FIG. 11A, the panel 602 is provided with a fitting projection portion 602a, and a second holder 401 is provided with a fitting recess portion 401a which fits on the projection portion 602a. By making the fitting recess portion 401a of the second holder 401 fit on the projection portion 602a of the panel 602, it is possible to increase the rigidity of the second holder 401. As illustrated in FIG. 11B, by performing a thread cutting work on a second holder 402 and a panel 702 and screwing the second holder 402 and the panel 702 by a screw 50 or the like, it is possible to increase the rigidity of the second holder 402.

By using different materials, the rigidity of the second holder may be set higher than that of the first holder. For instance, by using a rubber having, for instance, low elasticity (low Young's modulus) as the material of the first holder and using, for instance, polycarbonate having high elasticity (high Young's modulus) as the material of the second holder, it is possible for the rigidity of the second holder to be made higher than that of the first holder.

In the fourth embodiment, the first elastic member 504a is disposed between the case body 501 and the panel 502 and the second elastic member 504b is disposed between the panel 502 and the case cover 503. However, it is possible to dispose the elastic member either between the case body 501 and the panel 502 or between the panel 502 and the case cover 503, or it is possible to dispose three or more elastic members between the case body 501 and the panel 502 and between the panel 502 and the case cover 503.

Although the example of mounting the piezoelectric actuators 1, 10, 100a, and 100b on the mobile phone apparatuses 500, 600, 700, 800, and 900 has been described in the fourth embodiment, as long as the piezoelectric actuator as a vibrator or the like is employed, it is possible to apply the fourth embodiments to other electronic devices such as a small personal computer, a game machine, a PDA, a tablet terminal, and the like.

### EXAMPLES

Hereinafter, based on examples, the present invention will be more specifically described. The inventive concept of the present invention is not limited to the following examples. In the following examples 1 to 4, as a comparative object of the effect, a conventional piezoelectric actuator in which only one end of a piezoelectric ceramic vibrator is supported by a holder of a silicon rubber member having length of 5 mm, width of 5 mm, and thickness of 3 mm was used.

### Example 1

As the piezoelectric actuator used for the first embodiment, the piezoelectric actuator 1 of the first embodiment illustrated in FIG. 1 was formed. As the piezoelectric ceramic plate 20, a plate made of a piezoelectric ceramic material having a zirconate titanate having a length of 15 mm, a width of 5 mm, and a thickness of 1 mm as a composition was prepared, the silver electrodes 21a and 21b were formed on both main surfaces, and the polarization process was performed, thereby generating the piezoelectric ceramic vibrator 2.

As the first holder 3, a silicon rubber member having a length of 3 mm, a width of 5 mm, and a thickness of 3 mm was prepared. As the second holder 4, a silicon rubber member having a length of 5 mm, a width of 5 mm, and a thickness of 3 mm was prepared. In the side faces of the first and second holders 3 and 4, the notches 3a and 4a were formed, respectively. The ends of the piezoelectric ceramic vibrator 2 were fit to the notches 3a and 4a, respectively. Further, the piezoelectric actuator 1 was composed by adhesion using, for instance, an epoxy resin adhesive.

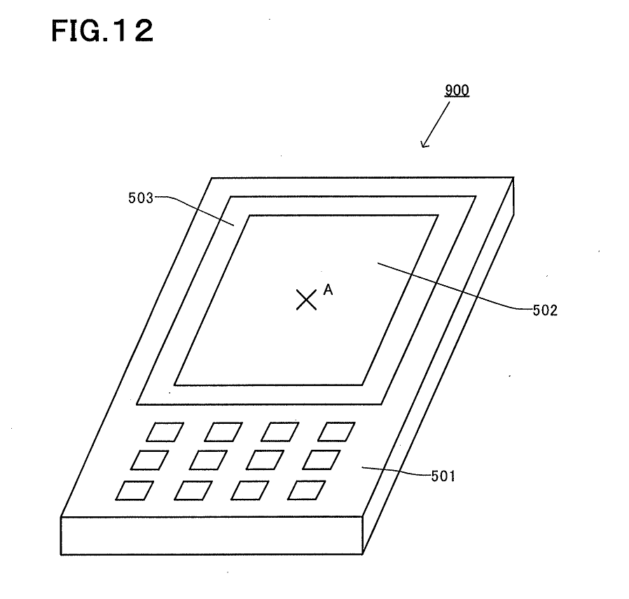

The piezoelectric actuator 1 composed as described above was mounted on the mobile phone apparatus 500 as described in FIG. 3, thereby composing a mobile phone apparatus 900 illustrated in FIG. 12. The configuration other than the piezoelectric actuator I in the mobile phone apparatus 900 is similar to that of a typical mobile phone apparatus. The piezoelectric actuator 1 is mounted on a face opposed to the case body 501 of the panel 502 and engaged and fixed in the slit 501b in the case body 501.

To confirm the effect of the piezoelectric actuator 1 of Example 1, a mobile phone apparatus having the configuration similar to that of the mobile phone apparatus 900 except for the piezoelectric actuator was prepared, and a conventional piezoelectric actuator was mounted in the same position as that of the piezoelectric actuator 1. Sinusoidal AC field of 10 Hz, 200 Hz, and 500 Hz was applied at a voltage effective value 1V to the piezoelectric actuator 1 and the conventional piezoelectric actuator, and vibration velocity and displacement at a measure point A in an almost center of the panel 502 was measured using a laser Doppler vibrometer.

As a result of the measurement, generation of a vibration amount which is 10 times at 10 Hz, 20 times at 200 Hz, and 25 times at 500 Hz as large as that of the conventional piezoelectric actuator was recognized. It was confirmed that, at any frequency, the vibration velocity and displacement of the piezoelectric actuator 1 is increased as compared to that of the conventional piezoelectric actuator, and the piezoelectric actuator 1 was found to be operable in a wider frequency domain.

### Example 2

As Example 2, the piezoelectric actuator 10 of the second embodiment illustrated in FIG. 4 was composed. The dimensions of the piezoelectric ceramic vibrator 2, the first holder 3, the holder 4, and the like are similar to those of Example 1. The composed piezoelectric actuator 10 was mounted on the mobile phone apparatus 600 as illustrated in FIG. 5, thereby forming the mobile phone apparatus 900 illustrated in FIG. 12. The piezoelectric actuator 10 is mounted on side faces of the panel 502 and engaged and fixed in the slit 501b in the case body 501.

To confirm the effect obtained by the piezoelectric actuator 10 of Example 2, a mobile phone apparatus configured in a manner similar to the mobile phone apparatus 600 was composed and a conventional piezoelectric actuator was mounted in the same position as that of the piezoelectric actuator 10. To the piezoelectric actuator 10 and the conventional piezoelectric actuator, sinusoidal AC field of 10 Hz, 200 Hz, and 500 Hz at the voltage effective value of IV was applied respectively, and the vibration velocity and displacement in the measurement point A in an almost center of the panel 502 was measured by using a laser Doppler vibrometer.

As a result of the measurement, it was confirmed that in the piezoelectric actuator 10 of Example 2, the vibration velocity and displacement which is 15 times at 10 Hz, 30 times at 200 Hz, and 40 times at 500 Hz as large as that in the conventional piezoelectric actuator was generated. It was found that, at any frequency of the above, the vibration velocity and displacement of the piezoelectric actuator 1 of Example 2 is increased as compared with that of the conventional piezoelectric actuator, and the piezoelectric actuator 1 was found to be operable in a wider frequency domain.

### Example 3

As Example 3, the piezoelectric actuators 100a and 100b of the third embodiment illustrated in FIG. 6B was composed. The dimensions of the piezoelectric ceramic vibrators 200a and 200b, the first holders 300a and 300b, the holders 400a and 400b, and the like are similar to those of Examples 1 and 2. The composed piezoelectric actuators 100a and 100b were mounted on the mobile phone apparatus 700 as illustrated in FIG. 7, thereby forming the mobile phone apparatus 900 illustrated in FIG. 12. The piezoelectric actuators 100a and 100b were mounted on side faces of the panel 502 and engaged and fixed in the slit 501b in the case body 501.

To confirm the effect obtained by the piezoelectric actuators 100a and 100b of the Example 3, a mobile phone apparatus constructed in a manner similar to the mobile phone apparatus 700 was composed and a conventional piezoelectric actuator was mounted. To the piezoelectric actuators 100a and 100b and the conventional piezoelectric actuator, sinusoidal AC field of 10 Hz, 200 Hz, and 500 Hz at the voltage effective value of 1V was applied, and the vibration velocity and displacement the measurement point A in an almost center of the panel 502 was measured by using a laser Doppler vibrometer.

As a result of the above measurement, it was confirmed that in the piezoelectric actuators 100a and 100b of Example 3, the vibration amount which is 30 times at 10 Hz, 40 times at 200 Hz, and 55 times at 500 Hz as large as that in the conventional piezoelectric actuator was generated. It was found that, at any frequency of the above frequencies, the vibration velocity and displacement of the piezoelectric actuators 100a and 100b in Example 3 is increased as compared with that of the conventional piezoelectric actuator, and it makes it possible for the piezoelectric actuators 100a and 100b to operate in a wider frequency domain.

### Example 4

As Example 4, by using the mobile phone apparatus 800 of the fourth embodiment illustrated in FIG. 9, the mobile phone apparatus 900 illustrated in FIG. 12 was composed. As each of the first and second elastic members 504a and 504b, a silicon rubber member having a thickness of 1 mm was prepared. The configuration of the piezoelectric actuator 10 is similar to that of Example 2.

To confirm the effect of the mobile phone apparatus 800 having the first and second elastic members 504a and 504b of Example 4, a typical mobile phone apparatus configured in a manner similar to the mobile phone apparatuses 500, 600, and 700 of Examples 1, 2, and 3 was composed and a conventional piezoelectric actuator was mounted. To the piezoelectric actuator 10 and the conventional piezoelectric actuator, sinusoidal AC field of 10 Hz, 200 Hz, and 500 Hz at the voltage effective value of 1V was applied, and the vibration velocity and displacement in the measurement point A in an almost center of the panel 502 was measured by using a laser Doppler vibrometer.

As a result of the measurement, it was confirmed that in the mobile phone apparatus 800 of Example 4, the vibration amount which is 30 times at 10 Hz, 40 times at 200 Hz, and 60 times at 500 Hz as large as that in a typical mobile phone apparatus on which the conventional piezoelectric actuator was mounted was composed. It was confirmed that, at any frequency, the vibration velocity and displacement of the mobile phone apparatus 800 having the first and second elastic members 504a and 504b of Example 4 is increased as compared with that of a typical mobile phone apparatus having a conventional piezoelectric actuator mounted thereon, and it makes it possible for the mobile phone apparatus 800 to operate in a wider frequency domain.

A part or all of the foregoing embodiments can also be described as the following supplementary notes, but the invention is not limited to the following.

(Supplementary Note 1)

A piezoelectric actuator comprising:

a piezoelectric ceramic vibrator that vibrates in a predetermined direction when electronic power is supplied;

a first holder connected to a plate-shaped member and supporting a first portion in the piezoelectric ceramic vibrator; and

a second holder connected to the plate-shaped member and supporting a second portion in the piezoelectric ceramic vibrator,

wherein the first holder is made of a material with rigidity to such a degree that it is deformed by vibration from the piezoelectric ceramic vibrator, the second holder is made of a material with rigidity to such a degree that it is not deformed by vibration from the piezoelectric ceramic vibrator,

the piezoelectric ceramic vibrator transmits vibration to the plate-shaped member via the piezoelectric ceramic vibrator and the first holder, and relative movement in the second portion in the piezoelectric ceramic vibrator with respect to the plate-shaped member is constrained by the second holder.

(Supplementary Note 2)

The piezoelectric actuator described in the supplementary note 1, wherein the piezoelectric ceramic vibrator is formed in a rectangular plate shape and polarized in a thickness direction and, when voltage is applied to electrodes formed on both faces of the piezoelectric ceramic vibrator, vibrates in a longitudinal direction,

the first and second holders support one end and the other end, respectively, in the longitudinal direction of the piezoelectric ceramic vibrator,

the piezoelectric ceramic vibrator transmits vibration to the plate-shaped member via the piezoelectric ceramic vibrator and the first holder, and relative movement in the other end with respect to the plate-shaped member is constrained by the second holder.

(Supplementary Note 3)

The piezoelectric actuator described in the supplementary note 2, wherein first and second fitting portions are formed in the first and second holders, respectively, and

the first and second holders are fit and fixed in the plate-shaped member via the first and second fitting portions.

(Supplementary Note 4)

The piezoelectric actuator according to any one of the supplementary notes 1 to 3, wherein first and second notches are formed in the first and second holders, respectively, and

the one end and the other end in the piezoelectric ceramic vibrator are fit in the first and second notches, respectively, so that the piezoelectric ceramic vibrator is supported by the first and second holders.

(Supplementary Note 5)

The piezoelectric actuator according to any one of the supplementary notes 1 to 4, wherein both the first and second holders are formed of the same material, and

volume of the second holder is larger than that of the first holder.

(Supplementary Note 6)

An electronic device having a case provided with a display,

wherein the plate-shaped member is a panel that is disposed in the case and protects the display from an external contact, and

the piezoelectric actuator according to any one of the supplementary notes 1 to 5 is disposed in the panel.

(Supplementary Note 7)

The electronic device described in the supplementary note 6, wherein a plurality of piezoelectric actuators are disposed in the panel, and two holders for fixing the piezoelectric actuator to the panel are disposed for each of the piezoelectric actuators.

(Supplementary Note 8)

The electronic device described in the supplementary note 6 or 7, wherein an elastic member for amplifying vibration of the piezoelectric actuator is disposed between the panel and the case.

(Supplementary Note 9)

The piezoelectric actuator described in any one of the supplementary notes 1 to 4, wherein the plurality of piezoelectric actuators include first and second piezoelectric actuators that have elongated shape and are orthogonal to each other,

two holders for supporting and fixing each of the piezoelectric actuators to the panel are disposed for the each of the first and second piezoelectric actuators,

one end of the first piezoelectric actuator and one end of the second piezoelectric actuator are disposed close to each other, and one holder supports the first and second piezoelectric actuators at the one ends that are close to each other.

(Supplementary Note 10)

An electronic device having a case provided with a display, wherein the plate-shaped member is a panel that is disposed in the case and protects the display from an external contact, and

the first and second piezoelectric actuators described in the supplementary note 9 are disposed in the panel.

The present application is based on Japanese Patent Application No. 2011-93276 filed on Apr. 19, 2011. The specification, the scope of claim for patent, and all of drawings of Japanese Patent Application No. 2011-93276 are incorporated by reference in the present specification.

### INDUSTRIAL APPLICABILITY

The present invention is useful when applied to a piezoelectric actuator used as a vibrator for vibrating an electronic device and an electronic device having a piezoelectric actuator mounted thereon.

### REFERENCE SIGNS LIST

1, 10, 100a, 100b Piezoelectric actuator
2, 200a, 200b, 201, 202 Piezoelectric ceramic vibrator
3, 30, 300a, 300b First holder
3a, 4a, 44a, 44b Notch
4, 40, 400, 400a, 400b, 401, 402 Second holder
20, 120a, 120b, 220 Piezoelectric ceramic plate
21a, 21b, 121a, 121b, 121c, 221a, 221b Electrode
22a, 22b Electric terminal
30b, 40b Notch
50 Screw
401a Fitting recess portion
500, 600, 700, 800, 900 Mobile phone apparatus
501 Case body
501a Bottomed recess
501b Slit
502, 602, 702 Panel
503 Case cover
504a First elastic member
504b Second elastic member
602a Fitting projection portion

1. A piezoelectric actuator comprising:
a piezoelectric ceramic vibrator that vibrates in a predetermined direction when electronic power is supplied;
a first holder connected to a plate-shaped member and supporting a first portion in the piezoelectric ceramic vibrator; and
a second holder connected to the plate-shaped member and supporting a second portion in the piezoelectric ceramic vibrator,
wherein the first holder is made of a material with rigidity to such a degree that it is deformed by vibration from the piezoelectric ceramic vibrator, the second holder is made of a material with rigidity to such a degree that it is not deformed by vibration from the piezoelectric ceramic vibrator,
the piezoelectric ceramic vibrator transmits vibration to the plate-shaped member via the piezoelectric ceramic vibrator and the first holder, and relative movement in the second portion in the piezoelectric ceramic vibrator with respect to the plate-shaped member is constrained by the second holder.

2. The piezoelectric actuator according to claim 1, wherein the piezoelectric ceramic vibrator is formed in a rectangular plate shape and polarized in a thickness direction and, when voltage is applied to electrodes formed on both faces of the piezoelectric ceramic vibrator, vibrates in a longitudinal direction,
the first and second holders support one end and the other end, respectively, in the longitudinal direction of the piezoelectric ceramic vibrator,
the piezoelectric ceramic vibrator transmits vibration to the plate-shaped member via the piezoelectric ceramic vibrator and the first holder, and relative movement in the other end with respect to the plate-shaped member is constrained by the second holder.

3. The piezoelectric actuator according to claim 2, wherein first and second fitting portions are formed in the first and second holders, respectively, and
the first and second holders are fit and fixed in the plate-shaped member via the first and second fitting portions.

4. The piezoelectric actuator according to claim 1, wherein first and second notches are formed in the first and second holders, respectively, and
the one end and the other end in the piezoelectric ceramic vibrator are fit in the first and second notches, respectively, so that the piezoelectric ceramic vibrator is supported by the first and second holders.

5. The piezoelectric actuator according to claim 1 4, wherein the first and second holders are formed of the same material, and
volume of the second holder is larger than that of the first holder.

6. An electronic device comprising a case provided with a display,
wherein the plate-shaped member is a panel that is disposed in the case and protects the display from an external contact, and
the piezoelectric actuator according to claim 1 is disposed in the panel.

7. The electronic device according to claim 6, wherein a plurality of piezoelectric actuators are disposed in the panel, and two holders for fixing the piezoelectric actuator to the panel are disposed for each of the piezoelectric actuators.

8. The electronic device according to claim 6, wherein an elastic member for amplifying vibration of the piezoelectric actuator is disposed between the panel and the case.

9. The piezoelectric actuator according to claim 1 4, wherein the plurality of piezoelectric actuators include first and second piezoelectric actuators that have elongated shape and are orthogonal to each other,
two holders for supporting and fixing each of the piezoelectric actuators to the panel are disposed for the each of the first and second piezoelectric actuators,
one end of the first piezoelectric actuator and one end of the second piezoelectric actuator are disposed close to each other, and one holder supports the first and second piezoelectric actuators at the one ends that are close to each other.

10. An electronic device comprising a case provided with a display,
wherein the plate-shaped member is a panel that is disposed in the case and protects the display from an external contact, and
the first and second piezoelectric actuators according to claim 9 are disposed in the panel.
